(19) United States
(12) Patent Application Publication
(10) Pub. No.: US 2025/0098344 A1
(43) Pub. Date: Mar. 20, 2025

(54) PHOTOELECTRIC CONVERSION APPARATUS, PHOTOELECTRIC CONVERSION SYSTEM, AND MOVING BODY

(71) Applicant: CANON KABUSHIKI KAISHA, Tokyo (JP)

(72) Inventors: HIROSHI SEKINE, Kanagawa (JP); KAZUHIRO MORIMOTO, Kanagawa (JP); JUNJI IWATA, Tokyo (JP)

(21) Appl. No.: 18/819,120

(22) Filed: Aug. 29, 2024

(30) Foreign Application Priority Data
Sep. 15, 2023 (JP) 2023-150287

(51) Int. Cl. H01L 27/146

(52) U.S. Cl. CPC H10F 39/182; H10F 39/8023; H10F 39/8063; H10F 39/807; H10F 39/809; H10F 39/811

(57) ABSTRACT

Photoelectric conversion apparatus includes semiconductor layer including pixel array region, peripheral region, scribe region, and isolation portion isolating the peripheral region and the scribe region. Each pixel includes avalanche photodiode having first semiconductor region of first conductivity type and second semiconductor region of second conductivity type. The peripheral region includes first region of the first conductivity type and second region of the second conductivity type. The second region and the second semiconductor region are supplied with the same voltage. The scribe region includes third region of the first conductivity type. Wiring structure includes first conductive path connecting the first region and the third region, and voltage supply line supplied with voltage between voltage of the first semiconductor region and voltage of the second semiconductor region. The first region and the voltage supply line are connected by second conductive path.

### BACKGROUND OF THE INVENTION

### Field of the Invention

The present disclosure relates to a photoelectric conversion apparatus, a photoelectric conversion system, and a moving body.

### Description of the Related Art

In an avalanche photodiode, a reverse bias voltage that can cause an avalanche multiplication operation is supplied between the anode and the cathode. Under such a reverse bias, electrons generated by the collision of photons with semiconductor atoms are accelerated by the strong electric field and collide with other semiconductor atoms, releasing a plurality of electrons. These electrons collide with other semiconductor atoms, releasing more electrons. This chain operation causes multiplication of electrons.

In a photoelectric conversion apparatus having an avalanche photodiode, a large electric field is required to cause avalanche multiplication. Therefore, if the chip end portion becomes charged, it is expected that an unintended current path is formed between the chip end portion and the anode. A current flowing through this current path causes holes and electrons to recombine, resulting in light emission that can be detected by a pixel. Although not very relevant to the present invention, Japanese Patent Laid-Open No. 2023-099383 describes an advantageous structure for reducing the influence of light entering the peripheral region of a photoelectric conversion apparatus.

### SUMMARY OF THE INVENTION

The present invention provides a technique advantageous in suppressing light emission caused by formation of an unintended current path.

A first aspect of the invention provides a photoelectric conversion apparatus including a semiconductor layer and a wiring structure, wherein the semiconductor layer includes a pixel array region including a plurality of pixels, a scribe region including an outer edge of the semiconductor layer, a peripheral region arranged between the pixel array region and the scribe region, and an isolation portion configured to electrically isolate the peripheral region and the scribe region, each of the plurality of pixels includes an avalanche photodiode including a first semiconductor region of a first conductivity type containing, as a majority carrier, a charge with a first polarity and a second semiconductor region of a second conductivity type containing, as a majority carrier, a charge with a second polarity different from the first polarity, the peripheral region includes a first region of the first conductivity type and a second region of the second conductivity type, and the second region is supplied with the same voltage as a voltage supplied to the second semiconductor region, the scribe region includes a third region of the first conductivity type, the wiring structure includes a first electrically conductive path configured to electrically connect the first region and the third region, and a voltage supply line supplied with a predetermined voltage between a voltage of the first semiconductor region and a voltage of the second semiconductor region, and the first region and the voltage supply line are electrically connected by a second electrically conductive path.

A second aspect of the invention provides a photoelectric conversion system comprising: a photoelectric conversion apparatus defined as the first aspect; and a signal processing unit configured to process a signal output from the photoelectric conversion apparatus.

A third aspect of the invention provides a moving body that includes a photoelectric conversion apparatus defined as the second aspect, comprising a control unit configured to control movement of the moving body using a signal output by the photoelectric conversion apparatus.

Further features of the present invention will become apparent from the following description of exemplary embodiments with reference to the attached drawings.

### BRIEF DESCRIPTION OF THE DRAWINGS

FIG. 1 is a view showing the basic arrangement of a photoelectric conversion apparatus according to an embodiment;

FIG. 2 is a view showing an example of the arrangement of a sensor substrate;

FIG. 3 is a view showing an example of the arrangement of a circuit substrate;

FIG. 4 is an equivalent circuit diagram of one pixel and a signal processing unit;

FIGS. 5A to 5C are views for explaining the operation of a pixel;

FIG. 6 is a plan view of a photoelectric conversion apparatus according to the first embodiment;

FIG. 7 is a sectional view of the photoelectric conversion apparatus according to the first embodiment;

FIG. 8 is a view exemplarily showing a problem;

FIG. 9 is a plan view of a photoelectric conversion apparatus according to the second embodiment;

FIG. 10 is a sectional view of the photoelectric conversion apparatus according to the second embodiment;

FIG. 11 is a sectional view of a photoelectric conversion apparatus according to the third embodiment;

FIG. 12 is a sectional view of a photoelectric conversion apparatus according to the fourth embodiment;

FIG. 13 a sectional view of a photoelectric conversion apparatus according to the fifth embodiment;

FIG. 14 is a sectional view of a photoelectric conversion apparatus according to the sixth embodiment;

FIG. 15 is a functional block diagram of a photoelectric conversion system according to the seventh embodiment;

FIGS. 16A and 16B are functional block diagrams of a photoelectric conversion system according to the eighth embodiment;

FIG. 17 is a functional block diagram of a photoelectric conversion system according to the ninth embodiment;

FIG. 18 is a functional block diagram of a photoelectric conversion system according to the tenth embodiment;

FIGS. 19A and 19B are views showing a photoelectric conversion system according to the eleventh embodiment;

FIGS. 20A and 20B are views showing a photoelectric conversion system according to the twelfth embodiment; and

FIG. 21 is a functional block diagram of a photoelectric conversion system according to the thirteenth embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

Embodiments of the present invention will be described in detail below based on the accompanying drawings. Note that in the following description, terms (for example, “upper”, “lower”, “right”, “left” and other terms including these terms) representing specific directions or positions are used, as necessary. These terms are used for easy understanding of the embodiments with reference to the accompanying drawings, and the meanings of the terms do not limit the technical scope of the present invention.

In this specification, a plan view corresponds to viewing a photoelectric conversion apparatus from a direction perpendicular to the light incident surface of a semiconductor layer, and is synonymous with orthogonal projection to the light incident surface. A sectional view corresponds to a plane in the direction perpendicular to the light incident surface of the semiconductor layer. Note that if the light incident surface of the semiconductor layer is rough microscopically, the plan view is defined with reference to the light incident surface of the semiconductor layer when viewed macroscopically.

In the following description of exemplary embodiments, the anode of an avalanche photodiode (to be also referred to as an APD hereinafter) is set to a fixed potential, and a signal is extracted from the cathode side. Therefore, a semiconductor region of the first conductivity type containing, as a majority carrier, a charge with the same first polarity as that of a signal charge is an n-type semiconductor region, and a semiconductor region of the second conductivity type containing, as a majority carrier, a charge with the second polarity different from that of the signal charge is a p-type semiconductor region. Note that even if the cathode of the APD is set to a fixed potential and a signal is extracted from the anode side, the present invention is viable. In this case, a semiconductor region of the first conductivity type containing, as a majority carrier, a charge with the same first polarity as that of a signal charge is a p-type semiconductor region, and a semiconductor region of the second conductivity type containing, as a majority carrier, a charge with the second polarity different from that of the signal charge is an n-type semiconductor region. A case in which one node of the APD is set to a fixed potential will be described below but the potentials of both the nodes may be variable.

In this specification, if a term “impurity concentration” is simply used, this indicates a net impurity concentration obtained by subtracting an impurity concentration compensated by impurities of an opposite conductivity type. That is, the “impurity concentration” indicates a net doping concentration. A region where the concentration of the added p-type impurities is higher than the concentration of the added n-type impurities is a p-type semiconductor region. To the contrary, a region where the concentration of the added n-type impurities is higher than the concentration of the added p-type impurities is an n-type semiconductor region.

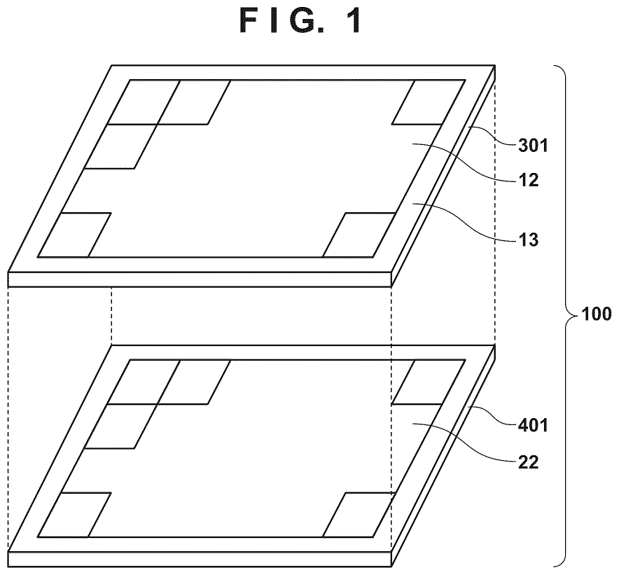

The basic arrangement and driving method common to photoelectric conversion apparatuses and driving methods therefor according to a plurality of embodiments to be described later will first be described with reference to FIGS. 1, 2, 3, 4, and 5A to 5C.

FIG. 1 is a view showing the basic arrangement of a photoelectric conversion apparatus 100 according to an embodiment. An example in which the photoelectric conversion apparatus 100 is formed as a stacked photoelectric conversion apparatus will be described but the present invention is applicable to photoelectric conversion apparatuses other than the stacked photoelectric conversion apparatus. The photoelectric conversion apparatus 100 can be formed by, for example, stacking a plurality of substrates including a sensor substrate 301 and a circuit substrate 401, and electrically connecting the plurality of substrates. The sensor substrate 301 can include a first semiconductor layer including photoelectric conversion elements 102 (to be described later), and a first wiring structure. The circuit substrate 401 can include a second semiconductor layer including a circuit such as signal processing units 103 (to be described later), and a second wiring structure. The photoelectric conversion apparatus 100 can be formed by stacking, for example, the second semiconductor layer, the second wiring structure, the first wiring structure, and the first semiconductor layer in this order. The photoelectric conversion apparatus to be described in each of the following embodiments can be, for example, a back-side illumination photoelectric conversion apparatus but the photoelectric conversion apparatus according to the present invention may be formed as a front-side illumination photoelectric conversion apparatus.

Each of the sensor substrate 301 and the circuit substrate 401 can be a chip diced from a wafer, but is not limited to the chip. For example, each substrate may be a wafer. The plurality of substrates may be obtained by stacking wafers and dicing them, or by forming chips and stacking or bonding the plurality of chips.

The sensor substrate 301 can include a semiconductor layer including a pixel array region 12 including a plurality of pixels, and a peripheral region 13 arranged on the periphery of the pixel array region 12. A region between the outer edge of the pixel array region 12 and the outer edge (the scribe region including the outer edge) of the sensor substrate 301 can be the peripheral region 13. In the peripheral region 13, circuit elements such as active elements may or may not be arranged. The circuit substrate 401 can include a semiconductor layer including a circuit region 22 where a signal detected by a pixel of the pixel array region 12 is processed.

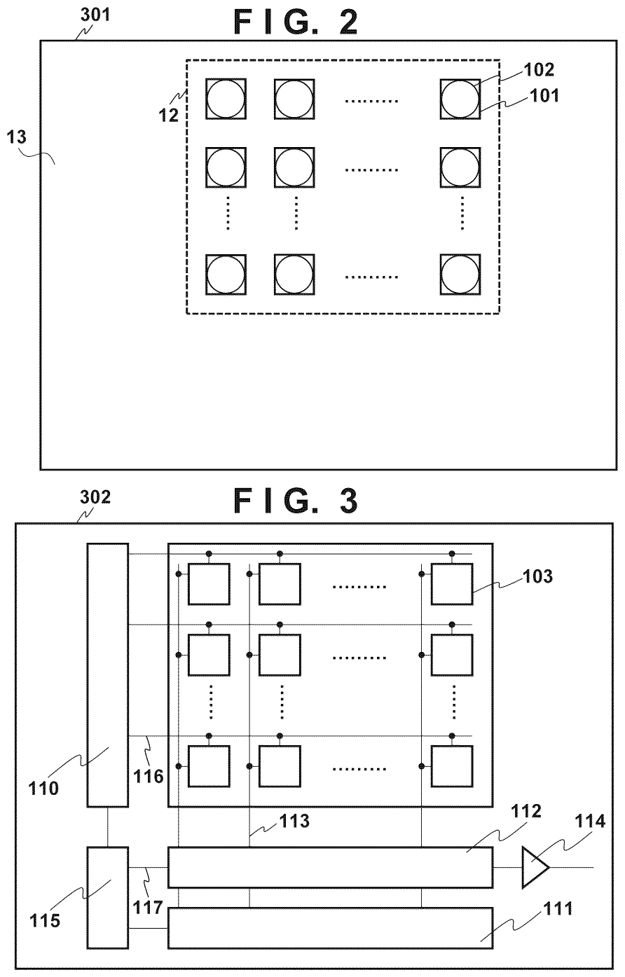

FIG. 2 is a view showing an example of the arrangement of the sensor substrate 301. In the pixel array region 12, a plurality of pixels 101 can be arranged in a two-dimensional array to form a plurality of rows and a plurality of columns. Each pixel 101 can include the photoelectric conversion element 102 including an avalanche photodiode (APD).

Each pixel 101 arranged in the pixel array region 12 can be a pixel for forming an image. However, if the sensor substrate 301 or the photoelectric conversion apparatus 100 is applied to Time of Flight (TOF), each pixel 101 need not always be a pixel for forming an image. That is, each pixel 101 may be a pixel for measuring the time at which light reaches and the amount of light.

FIG. 3 is a view showing the arrangement of the circuit substrate 401. The circuit substrate 401 can include, for example, the signal processing units 103 each configured to process a signal (electrical signal) generated according to charges (signal changes) generated by photoelectric conversion in the photoelectric conversion element 102. The circuit substrate 401 can also include a readout circuit 112, a control pulse generation unit 115, a horizontal scanning circuit unit 111, signal lines 113, and a vertical scanning circuit unit 110. One signal processing unit 103 can be provided for one pixel 101. Each photoelectric conversion element 102 shown in FIG. 2 and each signal processing unit 103 shown in FIG. 3 can electrically be connected via a connected wiring provided for each pixel 101.

For example, the vertical scanning circuit unit 110 can be configured to generate a second control pulse by receiving a first control pulse supplied from the control pulse generation unit 115, and supply the second control pulse to each pixel 101. The vertical scanning circuit unit 110 can include, for example, a logical circuit such as a shift register and an address decoder. A signal output from the photoelectric conversion element 102 of each pixel 101 can be processed by the signal processing unit 103 provided in correspondence with the pixel 101. The signal processing unit 103 can include a counter and a memory, and the memory can hold a digital value.

The horizontal scanning circuit unit 111 can be configured to supply, to the signal processing unit 103, a third control pulse for sequentially selecting columns to read out a digital signal from the memory of each pixel 101 that holds the signal. The circuit substrate 401 can include the plurality of signal lines 113. Signals are output, to the plurality of signal lines 113, from the signal processing units 103 assigned to the pixels 101 of the row selected by the vertical scanning circuit unit 110. The signals output to the plurality of signal lines 113 can be output, via an output circuit 114, to a recording unit or a signal processing unit outside the photoelectric conversion apparatus 100.

Referring to FIG. 2, the array of the photoelectric conversion elements 102 or the pixels 101 in the pixel array region 12 may be a one-dimensional array. Each signal processing unit 103 may be assigned to at least two photoelectric conversion elements 102 or pixels 101.

As shown in FIGS. 2 and 3, the plurality of signal processing units 103 can be arranged in a region overlapping the pixel array region 12 in a plan view. Then, the vertical scanning circuit unit 110, the horizontal scanning circuit unit 111, the readout circuit 112, the output circuit 114, and the control pulse generation unit 115 can be arranged to overlap the region between the outer edge of the sensor substrate 301 and the outer edge of the pixel array region 12 in a plan view. In other words, the vertical scanning circuit unit 110, the horizontal scanning circuit unit 111, the readout circuit 112, the output circuit 114, and the control pulse generation unit 115 can be arranged in a region overlapping the peripheral region 13 of the sensor substrate 301 in a plan view.

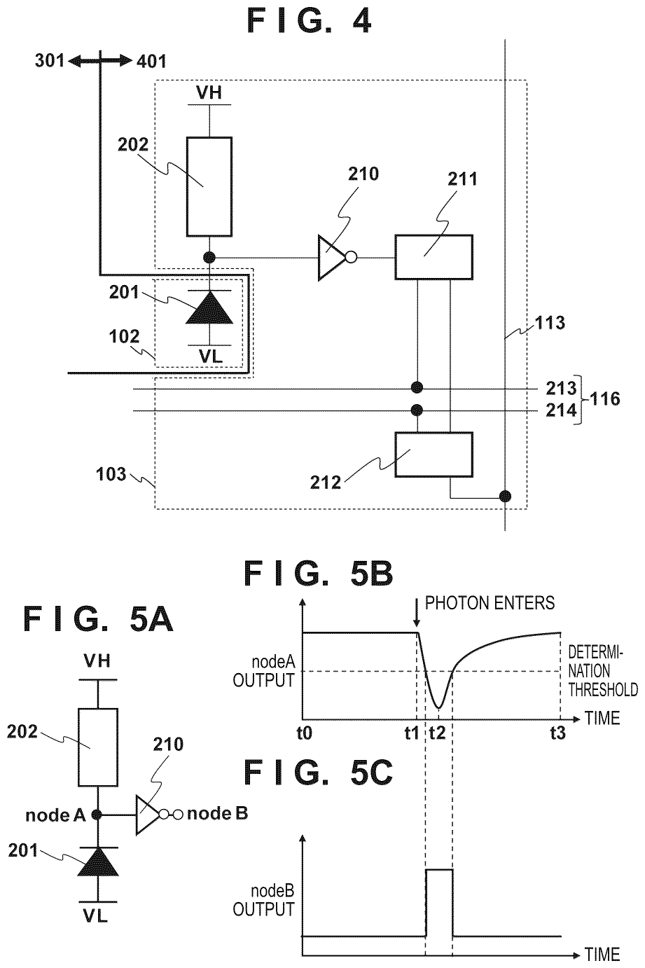

FIG. 4 exemplifies an equivalent circuit of one pixel 101 in FIG. 2 and one signal processing unit 103 in FIG. 3. An APD 201 generates charge pairs corresponding to incident light by photoelectric conversion. The anode of the APD 201 is supplied with a voltage VL (first voltage). The cathode of the APD 201 can be supplied with a voltage VH (second voltage) higher than the voltage VL supplied to the anode. A reverse bias voltage that can cause the APD 201 to perform an avalanche multiplication operation can be supplied between the anode and the cathode. By setting the state in which such reverse bias voltage is supplied between the anode and the cathode, charges generated by the incident light cause an avalanche multiplication operation, thereby generating an avalanche current.

A mode of operating an APD in a state in which the voltage between the anode and the cathode is higher than the breakdown voltage is called a Geiger mode. A mode of operating an APD in a state in which the voltage between the anode and the cathode is around or lower than the breakdown voltage is called a linear mode. An APD operated in the Geiger mode is called an SPAD. For example, the voltage VL (first voltage) is −30 V and the voltage VH (second voltage) is 1 V. The APD 201 may be operated in either the linear mode or the Geiger mode.

A quenching element 202 can be arranged to connect the APD 201 and a power supply for supplying the voltage VH. The quenching element 202 functions as a load circuit (quenching circuit) at the time of signal multiplication by an avalanche multiplication operation, and serves to suppress avalanche multiplication by suppressing the voltage supplied to the APD 201 (quenching operation). In addition, the quenching element 202 serves to return, to the voltage VH, the voltage supplied to the APD 201 by sending a current corresponding to a voltage drop caused by a quenching operation (recharging operation).

The signal processing unit 103 can include a waveform shaping unit 210, a counter circuit 211, and a selection circuit 212. The signal processing unit 103 may be a circuit including at least one of the waveform shaping unit 210, the counter circuit 211, and the selection circuit 212. The waveform shaping unit 210 can output a pulse signal by shaping the potential change of the cathode of the APD 201 obtained at the time of detection of a photon. As the waveform shaping unit 210, for example, an inverter circuit can be used. In FIG. 4, the waveform shaping unit 210 is formed by one inverter but the waveform shaping unit 210 may include a plurality of serially connected inverters or include another circuit having the waveform shaping effect.

The counter circuit 211 can count a pulse signal output from the waveform shaping unit 210, and hold a count value. The counter circuit 211 can be configured to reset the signal held in the counter circuit 211 when a control pulse pRES is supplied via a driving line 213. The selection circuit 212 can be supplied with a control pulse pSEL from the vertical scanning circuit unit 110 in FIG. 3 via a driving line 214 (not shown in FIG. 3) in FIG. 4, thereby switching between electrical connection and non-connection of the counter circuit 211 and the signal line 113. The selection circuit 212 can include, for example, a buffer circuit for outputting a signal.

A switch such as a transistor may be arranged between the quenching element 202 and the APD 201 and/or between the photoelectric conversion element 102 and the signal processing unit 103, thereby controlling electrical connection by the switch. Similarly, a switch such as a transistor may control supply of the voltage VH and/or the voltage VL to the photoelectric conversion element 102.

The photoelectric conversion apparatus 100 may be configured to acquire a pulse detection timing using a Time-to-Digital Converter (to be referred to as a TDC hereinafter) and a memory, instead of the counter circuit 211. The generation timing of the pulse signal output from the waveform shaping unit 210 can be converted into a digital signal by the TDC. A control pulse pREF (reference signal) can be supplied from the vertical scanning circuit unit 110 in FIG. 1 to the TDC via a driving line to measure the timing of the pulse signal. The TDC can acquire, as a digital signal, a signal obtained when the input timing of the signal output from each pixel via the waveform shaping unit 210 is set as the relative time with reference to the control pulse pREF.

FIGS. 5A to 5C are views schematically showing the relationship between the operation of the APD 201 and the output signal. FIG. 5A is a view showing the APD 201, the quenching element 202, and the waveform shaping unit 210 shown in FIG. 4. The input side of the waveform shaping unit 210 is indicated by node A and the output side of the waveform shaping unit 210 is indicated by node B. FIG. 5B shows the waveform change of node A in FIG. 5A, and FIG. 5C shows the waveform change of node B in FIG. 5A.

During a period from time t0 to time t1, a potential difference of VH−VL is applied to the APD 201 shown in FIG. 5A. When a photon enters the APD 201 at time t1, the APD 201 performs an avalanche multiplication operation, and an avalanche multiplication current flows through the quenching element 202, thereby dropping the voltage of node A. If the voltage drop amount becomes larger and the potential difference applied to the APD 201 becomes smaller, the avalanche multiplication operation of the APD 201 stops at time t2, and the voltage level of node A does not drop to a value less than a given value. After that, a current that compensates for the voltage drop from the voltage VL flows through node A during a period from time t2 to time t3, and node A is stabilized at the original potential level at time t3. At this time, a portion of the output waveform of node A, which exceeds a given threshold, is shaped by the waveform shaping unit 210, and output as a signal from node B.

Note that the arrangement of the signal lines 113 and the arrangement of the readout circuit 112 and the output circuit 114 are not limited to those shown in FIG. 3. For example, the signal lines 113 may be extended in the row direction, and the readout circuit 112 may be arranged at a position to which the signal lines 113 are extended.

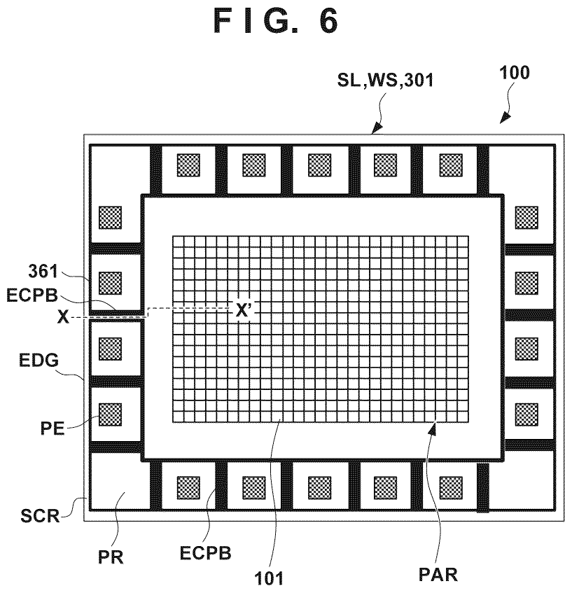

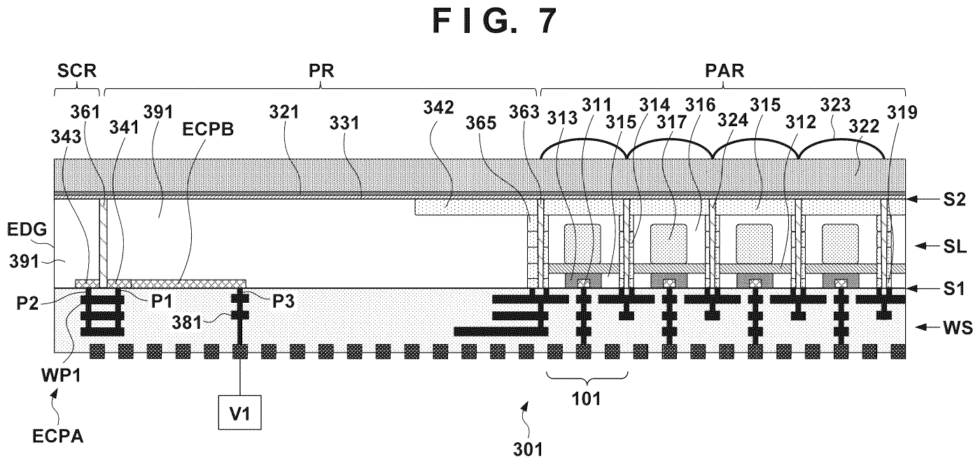

FIG. 6 shows a plan view of a photoelectric conversion apparatus 100 according to the first embodiment. FIG. 7 is a sectional view of the photoelectric conversion apparatus 100 according to the first embodiment. Here, FIG. 7 is a sectional view taken along a line X-X′in FIG. 6. The photoelectric conversion apparatus 100 or a sensor substrate 301 includes a semiconductor layer SL and a wiring structure WS. The semiconductor layer SL can include a pixel array region PAR including a plurality of pixels 101, a scribe region SCR including an outer edge EDG of the semiconductor layer SL, and a peripheral region PR arranged between the pixel array region PAR and the scribe region SCR. The semiconductor layer SL can also include an isolation portion 361 that electrically isolates the peripheral region PR and the scribe region SCR. The isolation portion 361 can have a structure similar to that of an insulating isolation portion 324 between the pixels 101 in the pixel array region PAR. The scribe region SCR is a portion left in the end portion of each sensor substrate 301 after a wafer where a plurality of the sensor substrates 301 are arrayed as a chip region is cut at scribe lines of the wafer to divide the plurality of the sensor substrates 301 into chips. That is, the scribe region SCR is a part of the scribe line. Each of the plurality of pixels 101 includes an avalanche photodiode 201. From another viewpoint, the photoelectric conversion apparatus 100, the sensor substrate 301, or the pixel array region includes a plurality of the avalanche photodiodes 201. The isolation portion 361 can be arranged to surround the peripheral region PR, preferably, surround the whole circumference of the peripheral region PR.

The semiconductor layer SL can include an isolation portion 363 arranged between the pixel array region PAR and the peripheral region PR. The isolation portion 363 can have a structure similar to that of the insulating isolation portion 324 between the pixels 101 in the pixel array region PAR. The pixel array region PAR can include a semiconductor region 316. The peripheral region PR can include a semiconductor region 391 electrically isolated from the pixel array region PAR. The scribe region SCR can include the semiconductor region 391. The semiconductor region 316 and the semiconductor region 391 can be semiconductor regions having the same conductivity type. The semiconductor region 316 and the semiconductor region 391 may have the first conductivity type or the second conductivity type, or may be intrinsic semiconductor regions. The semiconductor region 316 and the semiconductor region 391 can be formed by, for example, epitaxial growth.

The semiconductor layer SL has a first face S1 and a second face S2 on the opposite side of the first face S1. The wiring structure WS can be arranged such that the first face S1 is located between the second face S2 and the wiring structure WS. A pinning layer 331 can be arranged to cover the second face S2. The pinning layer 331 can extend to cover the pixel array region PAR, the peripheral region PR, and the scribe region SCR. From another viewpoint, the pinning layer 331 can extend to cover the pixel array region PAR and the peripheral region PR. The photoelectric conversion apparatus 100 can further include a microlens array 323. The semiconductor layer SL can be arranged between the microlens array 323 and the wiring structure WS.

Each pixel 101 includes the avalanche photodiode (APD 201). The APD 201 can include a first semiconductor region 311 of the first conductivity type as the cathode and a second semiconductor region 315 of the second conductivity type as the anode. The second semiconductor regions 315 of the plurality of pixels 101 may be electrically interconnected, and a common voltage can be supplied to the second semiconductor regions 315 of the plurality of pixels 101. The first conductivity type is a conductivity type containing, as a majority carrier, a charge with the first polarity. The second conductivity type is a conductivity type containing, as a majority carrier, a charge with the second polarity different from the first polarity. The first semiconductor region 311 of the first conductivity type can be arranged on the side of the first face S1 of the first semiconductor layer SL (pixel array region PAR). The second semiconductor region 315 of the second conductivity type can be arranged on the side of the second face S2 of the first semiconductor layer SL (pixel array region PAR). A voltage that can cause an avalanche multiplication operation can be supplied between the first semiconductor region 311 and the second semiconductor region 315. Each pixel 101 can include, between the first semiconductor region 311 as the cathode and the second semiconductor region 315 as the anode, a semiconductor region 313 of the first conductivity type arranged close to the first semiconductor region 311. The impurity concentration of the first conductivity type in the semiconductor region 313 is lower than that in the first semiconductor region 311 of the first conductivity type as the cathode.

Each pixel 101 can include a semiconductor region 312 of the second conductivity type between the first semiconductor region 311 of the first conductivity type as the cathode and the second semiconductor region 315 of the second conductivity type as the anode. For example, if the semiconductor region 312 serves as the same node as the second semiconductor region 315 as the anode, the semiconductor region 312 can also function as the anode. Then, a region between the first semiconductor region 311 and the semiconductor region 312 can be an avalanche multiplication region. The semiconductor region 316 of the first or second conductivity type can be arranged between the first face S1 and the semiconductor region 312 of the second conductivity type to surround the first semiconductor region 311 of the first conductivity type as the cathode. If the semiconductor region 316 has the first conductivity type, the impurity concentration of the first conductivity type in the semiconductor region 316 is lower than that in the semiconductor region 313. If the semiconductor region 316 has the second conductivity type, the impurity concentration of the second conductivity type in the semiconductor region 316 is lower than that in the semiconductor region 312 of the second conductivity type.

The semiconductor region 316 of the first or second conductivity type can be arranged between the semiconductor region 312 of the second conductivity type and the second semiconductor region 315 of the second conductivity type as the anode. If the semiconductor region 316 has the first conductivity type, the impurity concentration of the first conductivity type in the semiconductor region 316 may be lower than that in the semiconductor region 313. If the semiconductor region 316 has the second conductivity type, the impurity concentration of the second conductivity type in the semiconductor region 316 may be lower than that in the semiconductor region 312 of the second conductivity type.

The semiconductor region 316 can include a portion arranged between the second semiconductor region 315 of the second conductivity type as the anode and a semiconductor region 317 of the first conductivity type and a portion surrounding the side surface of the semiconductor region 317 of the first conductivity type.

An isolation region 314 of the second conductivity type can be arranged between the adjacent pixels 101 among the plurality of pixels 101. A contact region 319 of the second conductivity type can be arranged between the isolation region 314 of the second conductivity type and the first face S1 to be electrically connected to the isolation region 314 of the second conductivity type. The impurity concentration of the second conductivity type in the contact region 319 of the second conductivity type is higher than that in the isolation region 314 of the second conductivity type. The isolation region 314 of the second conductivity type can be arranged to be electrically connected to the second semiconductor region 315 of the second conductivity type as the anode. An anode voltage (anode potential) can be supplied to the contact region 319 of the second conductivity type via an electrically conductive path arranged in the wiring structure WL, thereby supplying the anode voltage (anode potential) to the second semiconductor region 315 of the second conductivity type as the anode.

The insulating isolation portion 324 may be arranged in the isolation region 314 of the second conductivity type. The insulating isolation portion 324 can include a trench formed in the isolation region 314 and an isolator arranged to cover at least the surface (inner surface) of the trench. The insulator may be a film, and an insulating material or a conductive material can be filled inside the film. The insulating isolation portion 324 can be called Deep Trench Isolation (DTI). The insulating isolation portion 324 or trench may be arranged to extend through the semiconductor layer SL, or may be arranged not to extend through the semiconductor layer SL. The insulating isolation portion 324 or trench may electrically isolate the isolation region 314 of the second conductivity type into an isolation region on the side of one pixel 101 and an isolation region on the side of the adjacent pixel 101. The insulating isolation portion 324 can include the trench, the insulator arranged to cover the inner surface of the trench, and a metal or a light shielding body arranged in the insulator.

The pinning layer 331 can be arranged on the side of the second face S2 of the second semiconductor region 315 of the second conductivity type as the anode. The pinning layer 331 can also be called a fixed charge film. The pinning layer 331 is arranged to be in contact with the second face S2, and can be formed by, for example, Atomic Layer Deposition (ALD). The pinning layer 331 can be made of, for example, a material selected from hafnium oxide, aluminum oxide, zirconium oxide, titanium oxide, tantalum oxide, and ruthenium oxide. The pinning layer 331 may include a plurality of layers. The above-described film covering the surface (inner surface) of the trench formed in the isolation region 314 may be the pinning layer 331.

The pinning layer 331 can be covered with an insulating film 321. The insulating film 321 can be, for example, a silicon oxide film, a silicon nitride film, or a silicon oxynitride film. The insulating film 321 may include a plurality of films. The insulating film 321 can be covered with a planarizing layer 322. The microlens array 323 can be arranged on the planarizing layer 322. In the example shown in FIG. 7, the photoelectric conversion apparatus 100 is a back-side illumination photoelectric conversion apparatus in which light enters the second face S2 of the semiconductor layer SL from the outside through the microlens array 323. However, the photoelectric conversion apparatus 100 may be formed as a front-side illumination photoelectric conversion apparatus. Note that although not shown, a filter layer such as a color filter or an infrared cut-off filter may be provided on the side of the second face S2 of the semiconductor layer SL, in addition to the planarizing layer 322.

The peripheral region PR can include a first region 341 of the first conductivity type containing, as a majority carrier, a charge with the first polarity, and a second region 342 of the second conductivity type containing, as a majority carrier, a charge with the second polarity different from the first polarity. The first region 341 and the second region 342 can be arranged in the semiconductor region 391 in the peripheral region PR. The second region 342 can be supplied with the same voltage as the voltage supplied to the second semiconductor region 315 of the pixel 101 (APD 201). Supplying the same voltage can mean that the voltages applied to respective regions are the same. The first region 341 and a second electrically conductive path ECPB form a charge discharge path for extracting a charge with the first polarity from the peripheral region PR (semiconductor region 391).

The scribe region SCR can include a third region 343 of the first conductivity type. If the semiconductor region 391 has the first conductivity type, the impurity concentration of the first conductivity type in the semiconductor region 391 is lower than that in each of the first region 341 and the third region 343. If the semiconductor region 391 has the second conductivity type, the impurity concentration of the second conductivity type in the semiconductor region 391 is lower than that in the second region 342 of the second conductivity type.

The wiring structure WS can include a first electrically conductive path ECPA that electrically connects the first region 341 of the first conductivity type and the third region 343 of the first conductivity type. The wiring structure WS can also include a voltage supply line 381 supplied with a predetermined voltage V1 (for example, −3 V) between the voltage (cathode voltage) of the first semiconductor region 311 of the APD 201 and the voltage (anode voltage) of the second semiconductor region 315 of the APD 201. The first region 341 of the peripheral region PR (semiconductor region 391) and the voltage supply line 381 can be electrically connected by the second electrically conductive path ECPB arranged in the peripheral region PR (semiconductor region 391). With this, the predetermined voltage V1 can be supplied to the first region 341 from the voltage supply line 381 via the second electrically conductive path ECPB, and further supplied to the third region 343 via the first electrically conductive path ECPA. With this arrangement, application of the voltage that causes avalanche multiplication between the first region 341 and the second region 342 can be prevented. Preventing avalanche multiplication prevents occurrence of light emission which is caused by recombination of charges due to formation of a current path. Note that the predetermined voltage V1 is supplied via a bonded portion between the sensor substrate and the circuit substrate in FIG. 7, but it may be supplied from the sensor substrate side without intervening the circuit substrate and bonded portion.

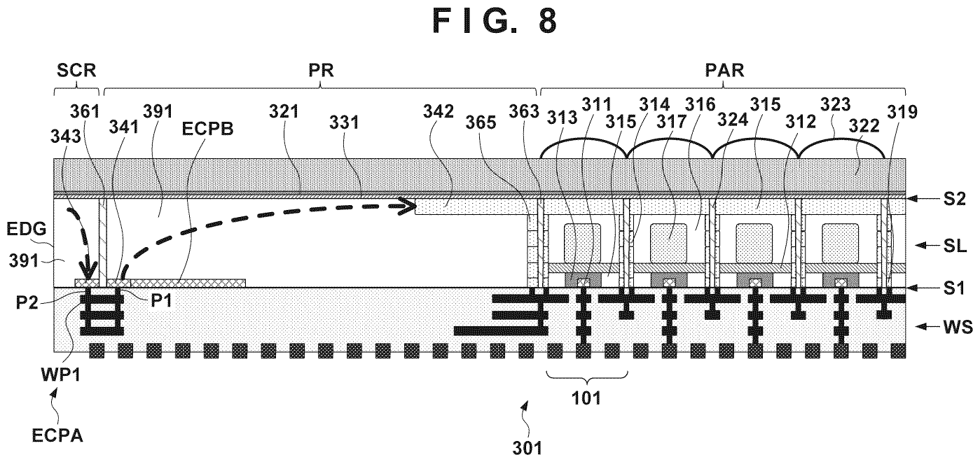

FIG. 8 schematically shows a problem that an unintended current path is formed when the scribe region SCR is charged. If the scribe region SCR is charged, a current path 371 extending from the semiconductor region 391 of the scribe region SCR to the second region 342 of the second conductivity type via the third region 343, the first electrically conductive path ECPA, the first region 341, and the semiconductor region 391 can be formed. The current flowing through the current path 371 causes recombination of charges in a p-n junction, thereby generating light. If an electric field which causes avalanche multiplication exists in the current path 371, the amount of charges flowing through the current path significantly increases, and this can strengthen the light emission.

To prevent this, as has been described above, in the first embodiment, the predetermined voltage V1 (for example, −3 V) between the cathode voltage and the anode voltage of the APD 201 is supplied to the first region 341 and the third region 343. This prevents occurrence of avalanche multiplication and generation of light caused by recombination of charges.

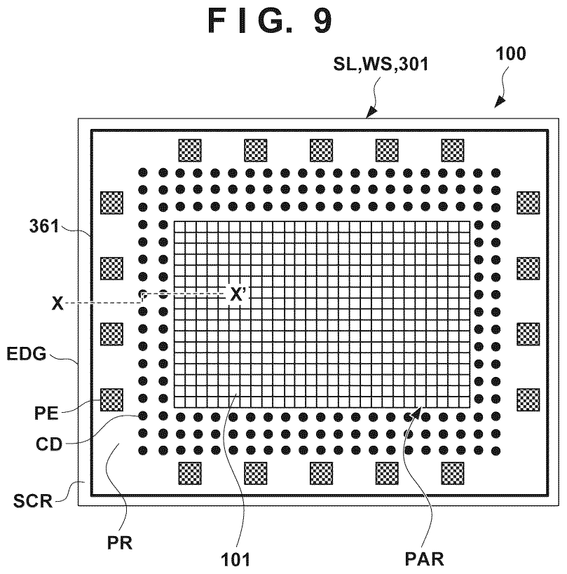

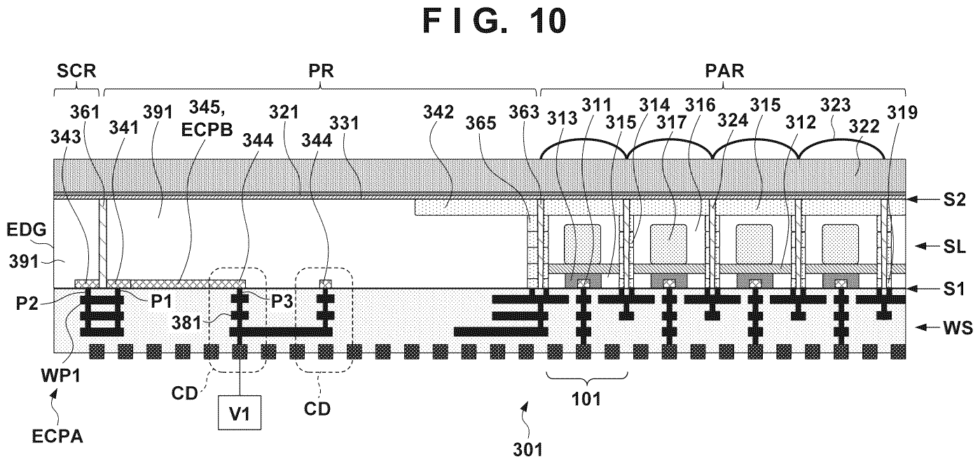

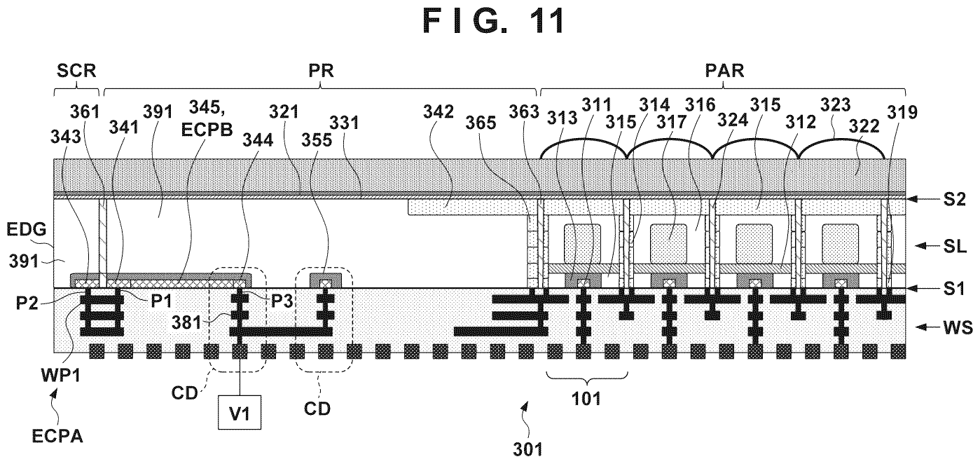

FIG. 9 is a plan view of a photoelectric conversion apparatus 100 according to the second embodiment. FIG. 6 is incorporated as another plan view of the photoelectric conversion apparatus 100 according to the second embodiment. FIG. 10 is a sectional view of the photoelectric conversion apparatus 100 according to the second embodiment. FIG. 10 is a sectional view taken along a line X-X′in FIGS. 6 and 9. Matters not mentioned as the second embodiment can follow the first embodiment. FIG. 9 shows an arrangement example of a charge discharge path CD in the photoelectric conversion apparatus 100 according to the second embodiment, and FIG. 6 shows an arrangement example of a second electrically conductive path ECPB in the photoelectric conversion apparatus 100 according to the second embodiment.

In the photoelectric conversion apparatus 100 according to the second embodiment, a peripheral region PR includes a fourth region 344 of the first conductivity type and a fifth region 345 of the first conductivity type. The fifth region of the first conductivity type can be arranged to electrically connect a first region 341 of the first conductivity type and the fourth region 344 of the first conductivity type. The fourth region 344 and the fifth region 345 can form at least a part of the second electrically conductive path ECPB. A voltage supply line 381 can be electrically connected to the fourth region 344.

The first region 341, the fourth region 344, the fifth region 345, and the voltage supply line 381 can form the charge discharge path CD for extracting a charge with the first polarity from the peripheral region PR (semiconductor region 391).

The fifth region 345 can be arranged in the same depth range as the first region 341 and the fourth region 344. From another viewpoint, the fifth region 345 can be arranged in the same depth range as the first region 341, a third region 343, and the fourth region 344. From still another viewpoint, the fifth region 345 can be arranged in the same depth range as the first region 341, the third region 343, the fourth region 344, and a first semiconductor region 311.

A first electrically conductive path ECPA can include, for example, an electrically conductive pattern WP1, a first plug P1 electrically connecting the electrically conductive pattern WP1 and the first region 341, and a second plug P2 electrically connecting the electrically conductive pattern WP1 and the third region 343. The voltage supply line 381 can include a third plug P3 electrically connected to the fourth region 344. The arrangement in which the fourth region 344 and the first region 341 are electrically connected by the fifth region 345 arranged in the semiconductor region 391 can provide a reasonable electrical resistance value between the fourth region 344 and the first region 341. This is advantageous in suppressing that an unintended high current flows between a scribe region SCR and the fourth region 344 when the scribe region SCR is charged.

In an example, the distance between the first plug P1 and the third plug P3 is larger than the distance between the first plug P1 and the second plug P2. Alternatively, the distance between the first plug P1 and the third plug P3 may be smaller than the distance between the first plug P1 and the second plug P2. In an example, the electrical resistance value between the first plug P1 and the third plug P3 is larger than the electrical resistance value between the first plug P1 and the second plug P2. Alternatively, the electrical resistance value between the first plug P1 and the third plug P3 may be smaller than the electrical resistance value between the first plug P1 and the second plug P2. In an example, the first plug P1 is arranged between the second plug P2 and the third plug P3.

FIG. 11 is a sectional view of a photoelectric conversion apparatus 100 according to the third embodiment. The third embodiment is a modification of the second embodiment, and matters not mentioned as the third embodiment can follow the second embodiment. The photoelectric conversion apparatus 100 according to the third embodiment includes a field relaxing region 355 of the first conductivity type arranged in a semiconductor region 391 to surround a fourth region 344 and a fifth region 345. From another viewpoint, the photoelectric conversion apparatus 100 according to the third embodiment includes the field relaxing region 355 of the first conductivity type arranged in the semiconductor region 391 to surround a first region 341, a third region 343, the fourth region 344, and the fifth region 345. The field relaxing region 355 is effective in suppressing formation of an unintended current path due to avalanche multiplication occurring when a scribe region SCR is charged, and suppressing light emission caused by recombination of charges.

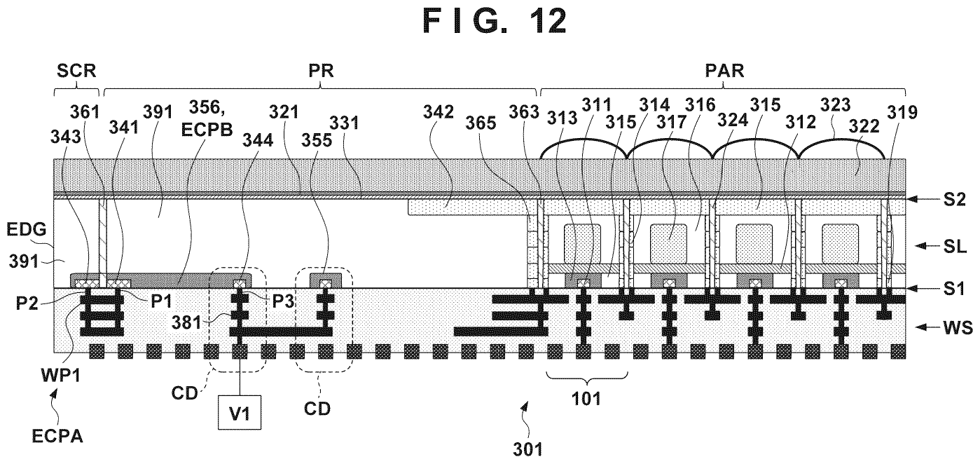

FIG. 12 is a sectional view of a photoelectric conversion apparatus 100 according to the fourth embodiment. The fourth embodiment is a modification of the third embodiment, and matters not mentioned as the fourth embodiment can follow the third embodiment. In the fourth embodiment, a peripheral region PR includes a fourth region 344 of the first conductivity type, and a sixth region 356 of the first conductivity type arranged to electrically connect a first region 341 and the fourth region 344. The fourth region 344 and the sixth region 356 can form at least a part of a second electrically conductive path ECPB. The sixth region 356 is a region where the impurity concentration of the first conductivity type is lower than in the first region 341 and the fourth region 344. For example, as compared to the third embodiment, this arrangement functions to increase the electrical resistance value between first region 341 and the fourth region 344. This is advantageous in suppressing that an unintended high current flows between a scribe region SCR and the fourth region 344 when the scribe region SCR is charged.

The sixth region 356 can serve as a field relaxing region of the first conductivity type arranged in a semiconductor layer SL to surround the first region 341 and the fourth region 344. That is, the sixth region 356 can include a portion that relaxes the electric field acting on the first region 341 and the fourth region 344. From another viewpoint, the sixth region 356 can serve as a field relaxing region of the first conductivity type arranged in a semiconductor region 391 to surround the first region 341, a third region 343, and the fourth region 344. That is, the sixth region 356 can include a portion that relaxes the electric field acting on the first region 341, the third region 343, and the fourth region 344. The sixth region 356 is effective in suppressing avalanche multiplication occurring when the scribe region SCR is charged, thereby preventing light emission caused by recombination of charges due to formation of an unintended current path.

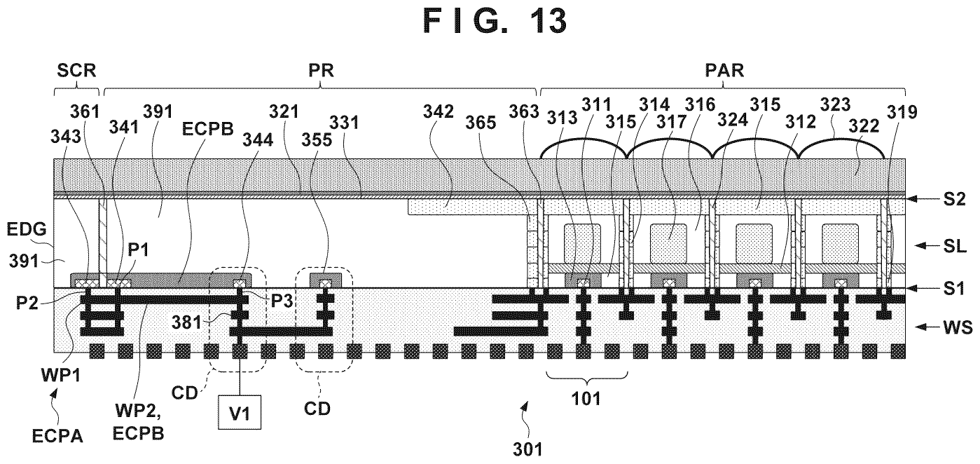

FIG. 13 is a sectional view of a photoelectric conversion apparatus 100 according to the fifth embodiment. The fifth embodiment is a modification of the fourth embodiment, and matters not mentioned as the fifth embodiment can follow the fourth embodiment. In the fifth embodiment, a second electrically conductive path ECPB further includes a second electrically conductive pattern WP2 arranged in a wiring structure WS to supply a predetermined voltage V1 to a first region 341 and a fourth region 344. The sixth embodiment can act to electrically connect the first region 341 and the fourth region 344 with low resistance.

In the fifth embodiment, a sixth region 356 can serve as a field relaxing region of the first conductivity type arranged in a semiconductor region 391 to surround the first region 341 and the fourth region 344. From another viewpoint, the sixth region 356 can serve as a field relaxing region of the first conductivity type arranged in the semiconductor region 391 to surround the first region 341, a third region 343, and the fourth region 344.

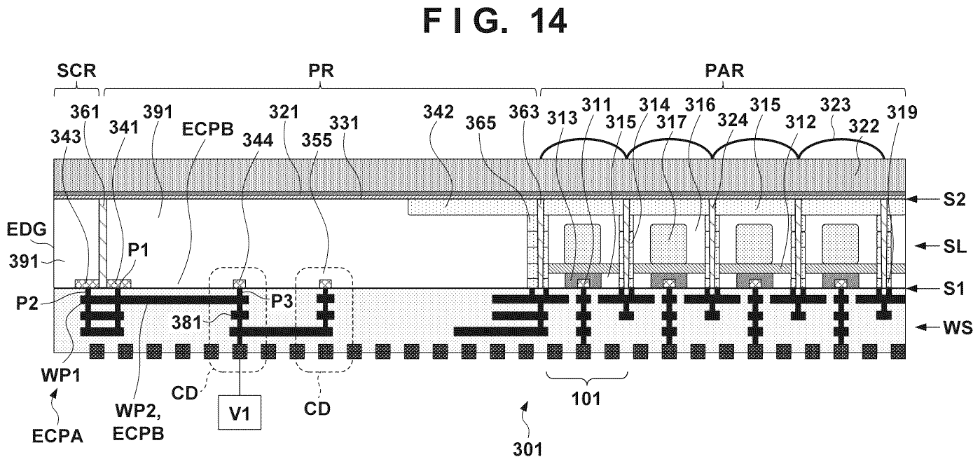

FIG. 14 is a sectional view of a photoelectric conversion apparatus 100 according to the sixth embodiment. The sixth embodiment is a modification of the fifth embodiment, and matters not mentioned as the sixth embodiment can follow the fifth embodiment. In the sixth embodiment, the sixth region 356 in the fifth embodiment is removed. The sixth embodiment is advantageous in preventing a current path extending from a scribe region SCR to a peripheral region PR which is formed when the scribe region SCR is charged.

Application examples of the photoelectric conversion apparatus 100 according to each of the first to sixth embodiments described above will be described below as the seventh to thirteenth embodiments.

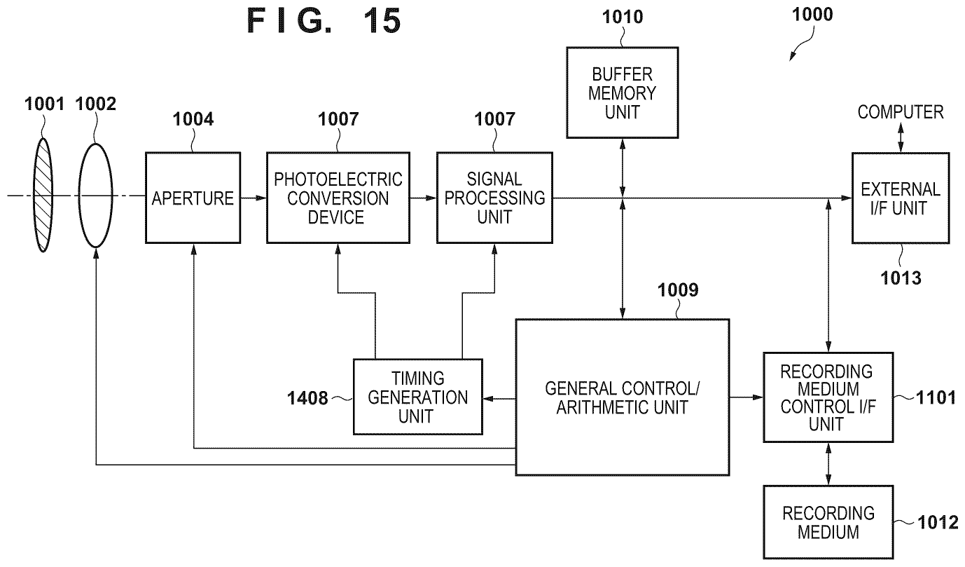

A photoelectric conversion system according to the seventh embodiment will be described with reference to FIG. 15. FIG. 15 is a block diagram showing the schematic arrangement of the photoelectric conversion system according to the seventh embodiment.

The above-described photoelectric conversion apparatus 100 is applicable to various kinds of photoelectric conversion systems. Examples of photoelectric conversion systems to which the photoelectric conversion apparatus is applicable are a digital still camera, a digital camcorder, a monitoring camera, a copying machine, a facsimile apparatus, a mobile phone, an in-vehicle camera, and an observation satellite. A camera module including an optical system such as a lens and an image capturing apparatus is also included in the photoelectric conversion systems. FIG. 15 exemplarily shows the block diagram of a digital still camera as an example of these.

A photoelectric conversion system 1000 exemplarily shown in FIG. 15 includes an image capturing apparatus 1004 as an example of the photoelectric conversion apparatus. The photoelectric conversion system 1000 also includes a lens 1002 that forms an optical image of an object on the image capturing apparatus 1004, an aperture 1003 configured to change the amount of light passing through the lens 1002, and a barrier 1001 configured to protect the lens 1002. The lens 1002 and the aperture 1003 form an optical system (optical apparatus) that condenses light to the image capturing apparatus 1004. The image capturing apparatus 1004 is the photoelectric conversion apparatus 100 (image capturing apparatus) according to one of the above-described embodiments, and converts the optical image formed by the lens 1002 into an electrical signal.

The photoelectric conversion system 1000 also includes a signal processing unit 1007 that is an image generation unit configured to generate an image by processing an output signal output from the image capturing apparatus 1004. The signal processing unit 1007 functions as a processing apparatus that performs an operation of performing various kinds of correction and compression as needed, thereby outputting image data. The signal processing unit 1007 may be formed on a semiconductor substrate on which the image capturing apparatus 1004 is provided or may be formed on a semiconductor substrate different from the image capturing apparatus 1004. In addition, the image capturing apparatus 1004 and the signal processing unit 1007 may be formed on the same semiconductor substrate.

The photoelectric conversion system 1000 further includes a memory unit 1010 configured to temporarily store image data, and an external interface unit (external I/F unit) 1013 configured to communicate with an external computer or the like. Furthermore, the photoelectric conversion system 1000 includes a recording medium 1012 such as a semiconductor memory configured to record or read out image capturing data, and a recording medium control I/F unit 1011 configured to perform record or readout for the recording medium 1012. The recording medium control I/F unit 1011 and the recording medium 1012 can form a part of a recording apparatus. Note that the recording medium 1012 may be incorporated in the photoelectric conversion system 1000 or may be detachable.

Furthermore, the photoelectric conversion system 1000 includes a general control/arithmetic unit 1009 that controls various kinds of operations and the entire digital still camera, and a timing generation unit 1408 that outputs various kinds of timing signals to the image capturing apparatus 1004 and the signal processing unit 1007. The general control/arithmetic unit 1009 and the timing generation unit 1008 can form a part of a control apparatus configured to control an operation of the photoelectric conversion system 1000. In this example, the timing signal and the like may be input from the outside, and the photoelectric conversion system 1000 need only include at least the image capturing apparatus 1004, and the signal processing unit 1007 that processes an output signal output from the image capturing apparatus 1004.

The image capturing apparatus 1004 outputs an image capturing signal to the signal processing unit 1007. The signal processing unit 1007 executes predetermined signal processing for the image capturing signal output from the image capturing apparatus 1004, and outputs image data. The signal processing unit 1007 generates an image using the image capturing signal. Although not shown in FIG. 15, a display apparatus such as a display for displaying the generated image may be arranged in the photoelectric conversion system 1000. As described above, according to this embodiment, it is possible to implement the photoelectric conversion system 1000 to which the photoelectric conversion apparatus 100 (image capturing apparatus) according to one of the above-described embodiments is applied.

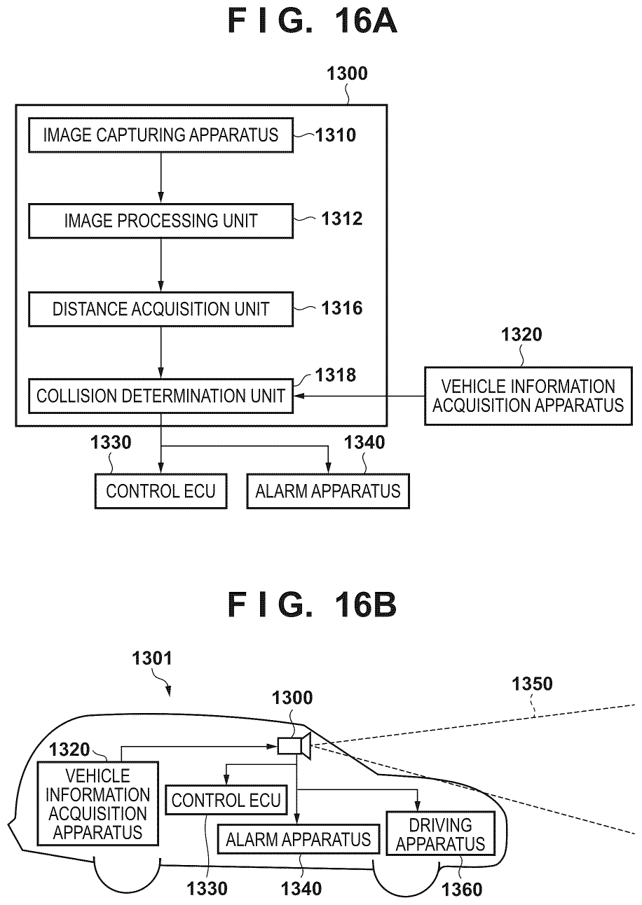

A photoelectric conversion system 1300 and a moving body 1301 according to the eighth embodiment will be described with reference to FIGS. 16A and 16B. FIGS. 16A and 16B are views showing the arrangement of the photoelectric conversion system 1300 and the moving body 1301 according to the eighth embodiment.

FIG. 16A shows an example of a photoelectric conversion system concerning an in-vehicle camera. The photoelectric conversion system 1300 includes an image capturing apparatus 1310. The image capturing apparatus 1310 is the photoelectric conversion apparatus 100 (image capturing apparatus) described in one of the above-described embodiments. The photoelectric conversion system 1300 includes an image processing unit 1312 that performs image processing for a plurality of image data acquired by the image capturing apparatus 1310. The photoelectric conversion system 1300 also includes a distance acquisition unit 1316 that calculates the distance up to a target object, and a collision determination unit 1318 that determines, based on the calculated distance, whether there is collision possibility. Here, the distance acquisition unit 1316 may acquire distance information up to a target object by using Time of Flight (ToF) method, or may acquire distance information by using parallax information or the like. That is, the distance information is information concerning a parallax, a defocus amount, a distance up to a target object, and the like. The collision determination unit 1318 may determine collision possibility using one of the pieces of distance information. The distance acquisition unit 1316 may be implemented by exclusively designed hardware, or may be implemented by a software module. The distance acquisition unit 1316 may be implemented by a Field Programmable Gate Array (FPGA), Application Specific Integrated Circuit (ASIC), or the like. Alternatively, the distance acquisition unit 1316 may be implemented by a combination of these.

The photoelectric conversion system 1300 is connected to a vehicle information acquisition apparatus 1320, and can acquire vehicle information such as a vehicle speed, a yaw rate, and a steering angle. The photoelectric conversion system 1300 is also connected to an ECU 1330 that is a control apparatus configured to output a control signal for generating a braking force to the vehicle based on the determination result of the collision determination unit 1318. Furthermore, the photoelectric conversion system 1300 is connected to an alarm apparatus 1340 that generates an alarm to the driver based on the determination result of the collision determination unit 1318. For example, if collision possibility is high as the determination result of the collision determination unit 1318, the ECU 1330 controls a driving apparatus (machine apparatus) 1360 to perform braking, releasing the accelerator pedal, or suppressing the engine output, thereby controlling the vehicle for avoiding collision and reducing damage. The alarm apparatus 1340 sounds an alarm, displays alarming information on the screen of a car navigation system or the like, or applies a vibration to the seat belt or a steering wheel, thereby making an alarm to the user.

In this embodiment, the periphery of the vehicle (moving body 1301), for example, the front or rear side is captured by the photoelectric conversion system 1300. FIG. 16B shows the photoelectric conversion system when capturing the front side (image capturing range 1350) of the vehicle. The vehicle information acquisition apparatus 1320 sends an instruction to the photoelectric conversion system 1300 or the image capturing apparatus 1310. With this configuration, it is possible to further improve the accuracy of distance measurement.

An example in which control is executed so as not to collide with another vehicle has been explained above. The photoelectric conversion system 1300 can also be applied to control of performing automated driving following another vehicle or control of performing automated driving without deviating from a lane. Furthermore, the photoelectric conversion system 1300 can be applied not only to a vehicle such as an automobile but also to, for example, a moving body (moving apparatus) such as a ship, an airplane, or an industrial robot. The moving body includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, an aircraft propeller, or the like. In addition, the photoelectric conversion system can be applied not only to a moving body but also to equipment that broadly uses object recognition, such as an intelligent transport system (ITS).

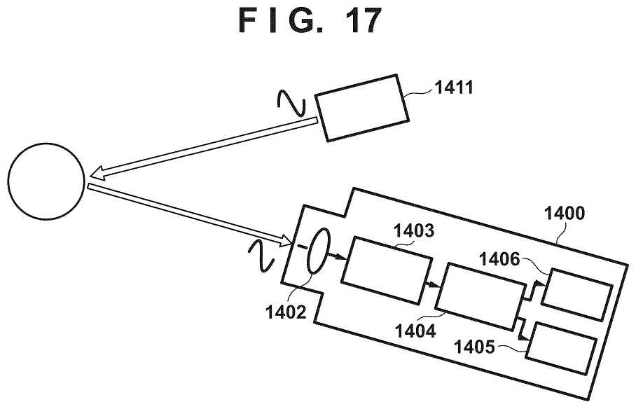

A photoelectric conversion system according to the ninth embodiment will be described with reference to FIG. 17. FIG. 17 is a block diagram showing an example of the arrangement of a distance image sensor 1401 as the photoelectric conversion system according to this embodiment.

As shown in FIG. 17, the distance image sensor 1401 includes an optical system 1402, a photoelectric conversion apparatus 1403, an image processing circuit 1404, a monitor 1405, and a memory 1406. Then, the distance image sensor 1401 can receive light (modulated light or pulsed light) projected from a light source apparatus 1411 toward an object and reflected by the surface of the object, thereby acquiring a distance image corresponding to the distance up to the object.

The optical system 1407 is formed by including one or a plurality of lenses, and guides image light (incident light) from the object to the photoelectric conversion apparatus 1408 and forms an image on the light-receiving surface (sensor portion) of the photoelectric conversion apparatus 1408.

As the photoelectric conversion apparatus 1408, the photoelectric conversion apparatus 100 of each of the above-described embodiments is applied, and a distance signal indicating a distance obtained from a light reception signal output from the photoelectric conversion apparatus 1408 is supplied to the image processing circuit 1404.

The image processing circuit 1404 performs image processing of creating a distance image based on the distance signal supplied from the photoelectric conversion apparatus 1408. Then, the distance image (image data) obtained by the image processing is supplied to and displayed on the monitor 1405, and supplied to and stored (recorded) in the memory 1406.

The distance image sensor 1401 having such arrangement can acquire, for example, a more correct distance image along with improvement in characteristic of pixels by applying the above-described photoelectric conversion apparatus 100.

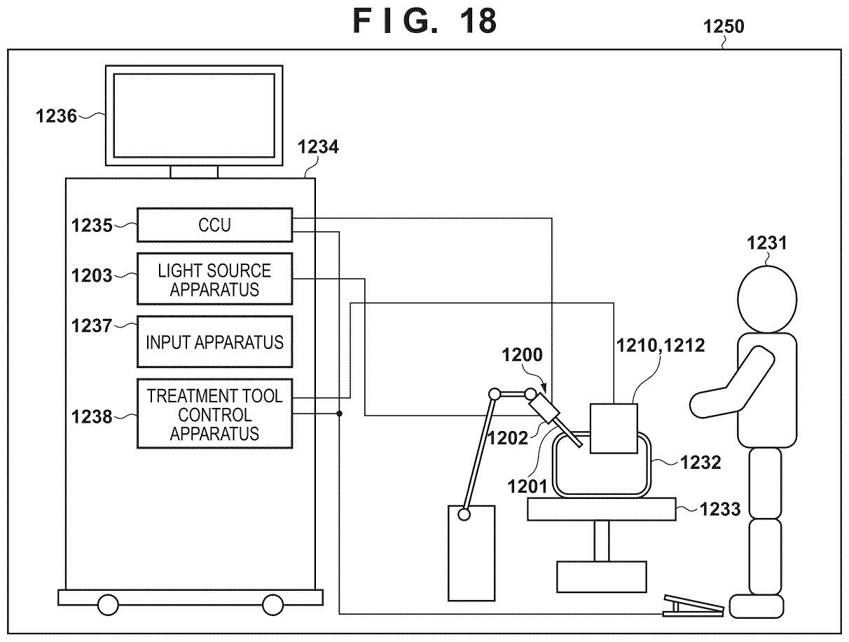

A photoelectric conversion system according to the tenth embodiment will be described with reference to FIG. 18. FIG. 18 is a view showing an example of the schematic arrangement of an endoscopic surgery system 1250 as the photoelectric conversion system according to this embodiment.

FIG. 18 shows a state in which an operator (doctor) 1231 operates on a patient 1232 on a patient bed 1233 using the endoscopic surgery system 1250. As shown in FIG. 18, the endoscopic surgery system 1250 is formed from an endoscope 1200, a surgical tool 1210, and a cart 1234 on which various apparatuses for endoscopic surgery are mounted.

The endoscope 1200 includes a lens barrel 1201 including a region of a predetermined length from the distal end, which is inserted into the body cavity of the patient 1232, and a camera head 1202 connected to the proximal end of the lens barrel 1201. In the example shown in FIG. 18, the endoscope 1200 formed as a so-called hard mirror including the hard lens barrel 1201 is shown but the endoscope 1200 may be formed as a so-called soft mirror including a soft lens barrel.

An opening in which an objective lens is fitted is provided at the distal end of the lens barrel 1201. A light source apparatus 1203 is connected to the endoscope 1200, and light generated by the light source apparatus 1203 is guided to the distal end of the lens barrel by a light guide extended inside the lens barrel 1201, and is emitted to an observation target in the body cavity of the patient 1232 via the objective lens. Note that the endoscope 1200 may be a forward-viewing endoscope or may be a forward-oblique viewing endoscope or side-viewing endoscope.

An optical system and a photoelectric conversion apparatus are provided in the camera head 1202, and reflected light (observation light) from the observation target is condensed by the optical system to the photoelectric conversion apparatus. The observation light is photoelectrically converted by the photoelectric conversion apparatus to generate an electrical signal corresponding to the observation light, that is, an image signal corresponding to an observation image. As the photoelectric conversion apparatus, the photoelectric conversion apparatus 100 (image capturing apparatus) described in each of the above-described embodiments can be used. The image signal is transmitted as RAW data to a Camera Control Unit (CCU) 1235.

The CCU 1235 is formed by a Central Processing Unit (CPU), a Graphics Processing Unit (GPU), and the like, and comprehensively controls the operations of the endoscope 1200 and a display apparatus 1236. Furthermore, the CCU 1235 receives an image signal from the camera head 1202, and performs, for the image signal, various kinds of image processes such as development processing (demosaic processing) for displaying an image based on the image signal.

Under the control of the CCU 1235, the display apparatus 1236 displays the image based on the image signal having undergone the image processing by the CCU 1235.

The light source apparatus 1203 is formed from a light source such as a Light Emitting Diode (LED), and supplies, to the endoscope 1200, irradiation light at the time of imaging an operation portion or the like.

An input apparatus 1237 is an input interface to the endoscopic surgery system 1250. The user can input various kinds of information or instructions to the endoscopic surgery system 1250 via the input apparatus 1237.

A treatment tool control apparatus 1238 controls driving of an energy treatment tool 1212 for ablation or incision of the tissue, sealing of a blood vessel, or the like.

The light source apparatus 1203 that supplies, to the endoscope 1200, irradiation light at the time of imaging an operation portion can be formed from, for example, a white light source formed by an LED, a laser light source, or a combination thereof. If the white light source is formed by a combination of RGB laser light sources, it is possible to accurately control the output intensity and output timing of each color (each wavelength), and thus the light source apparatus 1203 can adjust the white balance of a captured image. In this case, the observation target is time-divisionally irradiated with laser beams from the RGB laser light sources, respectively, and driving of the image sensor of the camera head 1202 is controlled in synchronism with the irradiation timings, thereby making it possible to time-divisionally capture images respectively corresponding to R, G, and B. In this method, it is possible to obtain a color image without providing color filters in the image sensor.

Driving of the light source apparatus 1203 may be controlled to change the intensity of light to be output for every predetermined time. It is possible to time-divisionally acquire images by controlling driving of the image sensor of the camera head 1202 in synchronism with the timing of changing the intensity of the light, and combine the images, thereby generating an image of a high dynamic range without so-called shadow detail loss or highlight detail loss.

The light source apparatus 1203 may be configured to supply light in a predetermined wavelength band corresponding to special light observation. In special light observation, for example, the wavelength dependency of light absorption in the body tissue is used. More specifically, by performing irradiation with light in a narrow band, as compared with irradiation light (that is, white light) at the time of normal observation, predetermined tissue such as a blood vessel in the mucous membrane surface layer is captured with high contrast. Alternatively, in special light observation, fluorescence observation for obtaining an image by using fluorescence generated by performing radiation with excitation light may be performed. In fluorescence observation, it is possible to, for example, irradiate body tissue with excitation light and observe fluorescence from the body tissue, or locally inject a reagent such as indocyanine green (ICG) to body tissue while irradiating the body tissue with excitation light corresponding to the fluorescence wavelength of the reagent, thereby obtaining a fluorescence image. The light source apparatus 1203 can be configured to supply narrow band light and/or excitation light corresponding to such special light observation.

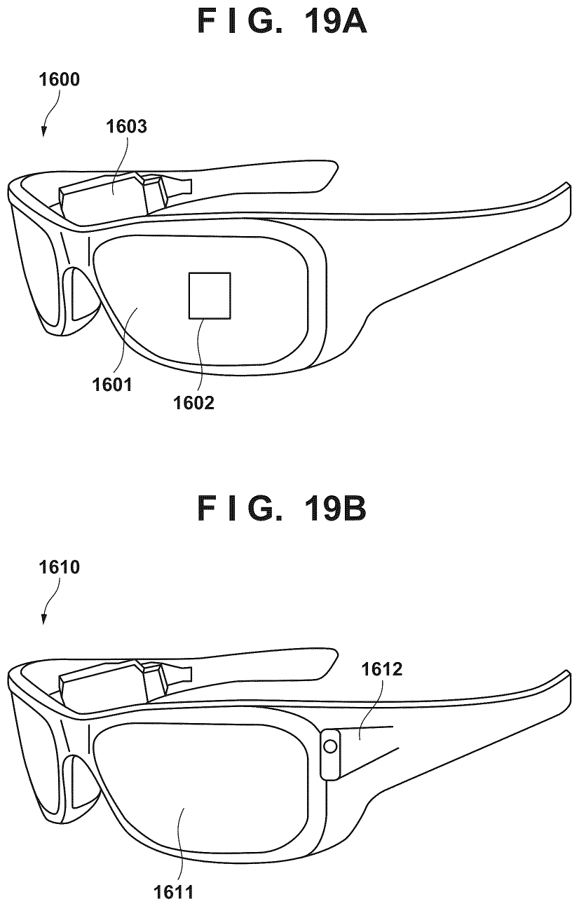

A photoelectric conversion system according to the eleventh embodiment will be described with reference to FIGS. 19A and 19B. FIG. 19A describes glasses 1600 (smartglasses) as the photoelectric conversion system according to this embodiment. The glasses 1600 include a photoelectric conversion apparatus 1602. The photoelectric conversion apparatus 1602 is the photoelectric conversion apparatus 100 (image capturing apparatus) described in each of the above embodiments. A display apparatus including the light emitting apparatus such as an OLED or LED may be provided on the back surface side of a lens 1601. One or a plurality of photoelectric conversion apparatuses 1602 may be provided. Alternatively, a plurality of kinds of photoelectric conversion apparatuses may be used in combination. The arrangement position of the photoelectric conversion apparatus 1602 is not limited to that shown in FIG. 19A.

The glasses 1600 further include a control apparatus 1603. The control apparatus 1603 functions as a power supply that supplies electric power to the photoelectric conversion apparatus 1602 and the above-described display apparatus. In addition, the control apparatus 1603 controls the operations of the photoelectric conversion apparatus 1602 and the display apparatus. An optical system configured to condense light to the photoelectric conversion apparatus 1602 is formed on the lens 1601.

FIG. 19B describes glasses 1610 (smartglasses) according to an application example. The glasses 1610 include a control apparatus 1612, and a photoelectric conversion apparatus corresponding to the photoelectric conversion apparatus 1602 and a display apparatus are mounted on the control apparatus 1612. The photoelectric conversion apparatus in the control apparatus 1612 and an optical system configured to project light emitted from the display apparatus are formed in a lens 1611, and an image is projected to the lens 1611. The control apparatus 1612 functions as a power supply that supplies electric power to the photoelectric conversion apparatus and the display apparatus, and controls the operations of the photoelectric conversion apparatus and the display apparatus. The control apparatus may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a plan view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display apparatus according to the embodiment can include a photoelectric conversion apparatus including a light receiving element, and control a displayed image of the display apparatus based on the line-of-sight information of the user from the photoelectric conversion apparatus.

More specifically, the display apparatus decides a first visual field region at which the user is gazing and a second visual field region other than the first visual field region based on the line-of-sight information. The first visual field region and the second visual field region may be decided by the control apparatus of the display apparatus, or those decided by an external control apparatus may be received. In the display region of the display apparatus, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority may be decided from the first display region and the second display region based on line-of-sight information. The first visual field region and the second visual field region may be decided by the control apparatus of the display apparatus, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target object ahead the line of sight from the image of the eyeball using the image of the eyeball and the direction of actual viewing of the eyeball in the image as supervised data. The AI program may be held by the display apparatus, the photoelectric conversion apparatus, or an external apparatus. If the external apparatus holds the AI program, it is transmitted to the display apparatus via communication.

When performing display control based on line-of-sight detection, smartglasses further including a photoelectric conversion apparatus configured to capture the image of the outside can preferably be applied. The smartglasses can display the captured outside image information in real time.

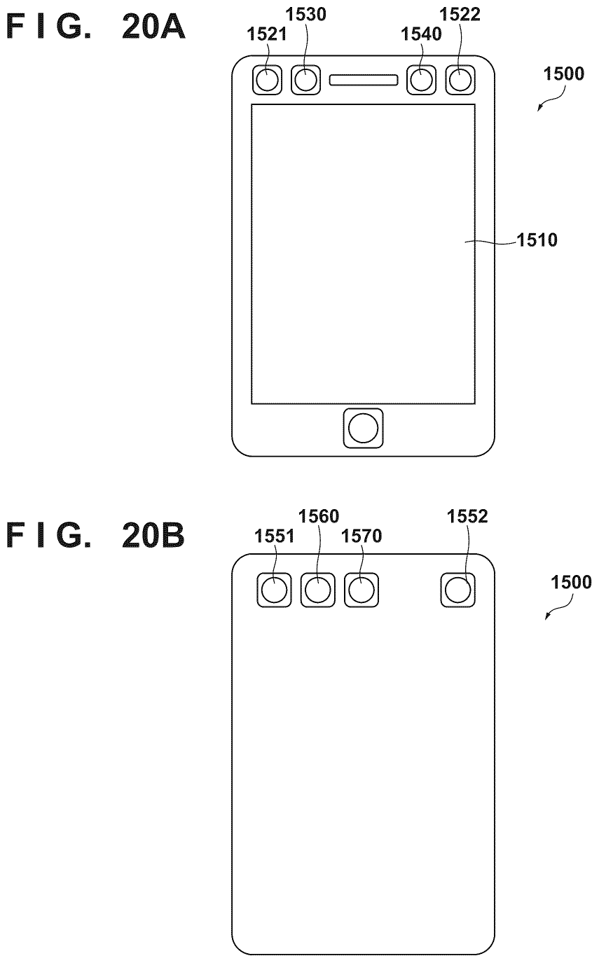

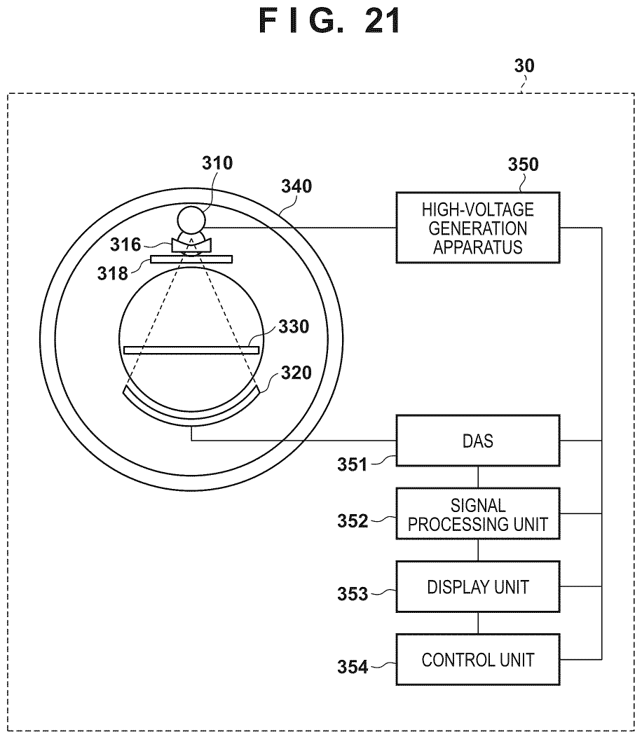

The twelfth embodiment will be described with reference to FIGS. 20A and 20B. The above-described photoelectric conversion apparatus and photoelectric conversion system may be applied to, for example, electronic equipment such as a so-called smartphone or tablet.

FIGS. 20A and 20B are views showing an example of electronic equipment 1500 on which the photoelectric conversion apparatus is mounted. FIG. 20A shows the front surface side of the electronic equipment 1500, and FIG. 20B shows the back surface side of the electronic equipment 1500.

As shown FIG. 20A, a display 1510 that displays an image is arranged at the center of the front surface of the electronic equipment 1500. Then, front cameras 1521 and 1522 for each of which the above-described photoelectric conversion apparatus 100 is used, an IR light source 1530 that emits infrared rays, and a visible light source 1540 that emits visible light are arranged along the upper side of the front surface of the electronic equipment 1500.

As shown in FIG. 20B, rear cameras 1551 and 1552 for each of which the above-described photoelectric conversion apparatus 100 is used, an IR light source 1560 that emits infrared rays, and a visible light source 1570 that emits visible light are arranged along the upper side of the back surface of the electronic equipment 1500.

By applying the above-described photoelectric conversion apparatus 100, the electronic equipment 1500 having the above arrangement can capture, for example, an image of higher quality. Note that the photoelectric conversion apparatus can be applied to electronic equipment such as an infrared sensor, a distance measurement sensor using an active infrared source, a security camera, or a personal or biometric authentication camera. This can improve the accuracy and performance of the electronic equipment.

FIG. 21 is a block diagram of an X-ray CT apparatus according to this embodiment. The above-described photoelectric conversion apparatus 100 is applicable to a detector of the X-ray CT apparatus. An X-ray CT apparatus 30 according to this embodiment includes an X-ray generation unit 310, a wedge 316, a collimator 318, an X-ray detection unit 320, a top plate 330, a rotating frame 340, and a high-voltage generation apparatus 350. The X-ray CT apparatus 30 also includes a Data Acquisition System (DAS) 351, a signal processing unit 352, a display unit 353, and a control unit 354.

The X-ray generation unit 310 is formed from, for example, a vacuum tube that generates X-rays. The vacuum tube of the X-ray generation unit 310 is supplied with a filament current and a high voltage from the high-voltage generation apparatus 350. When thermoelectrons are emitted from a cathode (filament) to an anode (target), X-rays are generated.

The wedge 316 is a filter that adjusts the amount of X-rays emitted from the X-ray generation unit 310. The wedge 316 attenuates the amount of X-rays so that the X-rays emitted from the X-ray generation unit 310 to an object has a predetermined distribution. The collimator 318 is formed from a lead plate that narrows the irradiation range of the X-rays having passed through the wedge 316. The X-rays generated by the X-ray generation unit 310 is formed in a cone beam shape via the collimator 318, and the object on the top plate 330 is irradiated with the X-rays.

The X-ray detection unit 320 is formed using the above-described photoelectric conversion apparatus 100. The X-ray detection unit 320 detects the X-rays having passed through the object from the X-ray generation unit 310, and outputs a signal corresponding to the amount of the X-rays to the DAS 351.

The rotating frame 340 is annular, and is configured to be rotatable. The X-ray generation unit 310 (the wedge 316 and the collimator 318) and the X-ray detection unit 320 are arranged to face each other in the rotating frame 340. The X-ray generation unit 310 and the X-ray detection unit 320 can rotate together with the rotating frame 340.

The high-voltage generation apparatus 350 includes a boosting circuit, and outputs a high voltage to the X-ray generation unit 310. The DAS 351 includes an amplification circuit and an A/D conversion circuit, and outputs, as digital data, a signal from the X-ray detection unit 320 to the signal processing unit 352.

The signal processing unit 352 includes a Central Processing Unit (CPU), a Read Only Memory (ROM), and a Random Access Memory (RAM), and can execute image processing and the like for the digital data. The display unit 353 includes a flat display apparatus or the like, and can display an X-ray image. The control unit 354 includes a CPU, a ROM, a RAM, and the like, and controls the operation of the overall X-ray CT apparatus 30.

The above-described embodiments can be changed appropriately without departing from the technical concept. Note that contents disclosed in this specification include not only contents described in this specification but also all items that can be grasped from this specification and its accompanying drawings. The contents disclosed in this specification include a complementary set of concepts described in this specification. That is, if, for example, “A is larger than B” is described in this specification, this specification is considered to disclose “A is not larger than B” even if a description of “A is not larger than B” is omitted. This is because if “A is larger than B” is described, it is assumed that a case in which “A is not larger than B” has been considered.

According to the present invention, a technique advantageous in suppressing light emission caused by formation of an unintended current path is provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-150287, filed Sep. 15, 2023, which is hereby incorporated by reference herein in its entirety.

What is claimed is:

1. A photoelectric conversion apparatus including a semiconductor layer and a wiring structure, wherein
the semiconductor layer includes a pixel array region including a plurality of pixels, a scribe region including an outer edge of the semiconductor layer, a peripheral region arranged between the pixel array region and the scribe region, and an isolation portion configured to electrically isolate the peripheral region and the scribe region,
each of the plurality of pixels includes an avalanche photodiode including a first semiconductor region of a first conductivity type containing, as a majority carrier, a charge with a first polarity and a second semiconductor region of a second conductivity type containing, as a majority carrier, a charge with a second polarity different from the first polarity,
the peripheral region includes a first region of the first conductivity type and a second region of the second conductivity type, and the second region is supplied with the same voltage as a voltage supplied to the second semiconductor region,
the scribe region includes a third region of the first conductivity type,
the wiring structure includes a first electrically conductive path configured to electrically connect the first region and the third region, and a voltage supply line supplied with a predetermined voltage between a voltage of the first semiconductor region and a voltage of the second semiconductor region, and
the first region and the voltage supply line are electrically connected by a second electrically conductive path.

2. The apparatus according to claim 1, wherein
the isolation portion is arranged to surround a whole circumference of the peripheral region.

3. The apparatus according to claim 1, wherein
the peripheral region further includes a fourth region of the first conductivity type, and a fifth region of the first conductivity type configured to electrically connect the first region and the fourth region, and
the fourth region and the fifth region form at least a part of the second electrically conductive path.

4. The apparatus according to claim 3, wherein
the fifth region is arranged in the same depth range as the fourth region.

5. The apparatus according to claim 3, wherein
the first electrically conductive path includes an electrically conductive pattern, a first plug configured to electrically connect the electrically conductive pattern and the first region, and a second plug configured to electrically connect the electrically conductive pattern and the third region, and
the voltage supply line includes a third plug electrically connected to the fourth region.

6. The apparatus according to claim 5, wherein
a distance between the first plug and the third plug is larger than a distance between the first plug and the second plug.

7. The apparatus according to claim 5, wherein
an electrical resistance value between the first plug and the third plug is larger than an electrical resistance value between the first plug and the second plug.

8. The apparatus according to claim 5, wherein
the first plug is arranged between the second plug and the third plug.

9. The apparatus according to claim 3, including
a field relaxing region of the first conductivity type arranged in the semiconductor layer to surround the fourth region and the fifth region.

10. The apparatus according to claim 3, including
a field relaxing region of the first conductivity type arranged in the semiconductor layer to surround the first region, the third region, the fourth region, and the fifth region.

11. The apparatus according to claim 1, wherein
the peripheral region includes a fourth region of the first conductivity type, and a sixth region of the first conductivity type arranged to electrically connect the first region and the fourth region,
the fourth region and the sixth region form at least a part of the second electrically conductive path, and
an impurity concentration of the first conductivity type in the sixth region is lower than in the first region and the fourth region.

12. The apparatus according to claim 11, wherein
the sixth region includes a portion arranged to surround the first region and the fourth region, and configured to relax an electric field acting on the first region and the fourth region.

13. The apparatus according to claim 11, wherein
the sixth region includes a portion arranged to surround the first region, the third region, and the fourth region, and configured to relax an electric field acting on the first region, the third region, and the fourth region.

14. The apparatus according to claim 11, wherein
the second electrically conductive path further includes a second electrically conductive pattern arranged in the wiring structure to supply the predetermined voltage to the first region and the fourth region.

15. The apparatus according to claim 1, wherein
the peripheral region further includes a fourth region of the first conductivity type, and
the second electrically conductive path includes a second electrically conductive pattern arranged in the wiring structure to supply the predetermined voltage to the first region and the fourth region.

16. The apparatus according to claim 1, wherein
the semiconductor layer has a first face and a second face on an opposite side of the first face,
the wiring structure is arranged such that the first face is located between the second face and the wiring structure, and
a pinning layer is arranged to cover the second face.

17. The apparatus according to claim 16, wherein
the pinning layer extends to cover the pixel array region, the peripheral region, and the scribe region.

18. The apparatus according to claim 1, further comprises a microlens array,
wherein the semiconductor layer is arranged between the microlens array and the wiring structure.

19. A photoelectric conversion system comprising:
a photoelectric conversion apparatus defined in claim 1; and
a signal processing unit configured to process a signal output from the photoelectric conversion apparatus.

20. A moving body that includes a photoelectric conversion apparatus defined in claim 1, comprising
a control unit configured to control movement of the moving body using a signal output by the photoelectric conversion apparatus.
